(19) United States
(12) Patent Application Publication
(10) Pub. No.: US 2002/0130715 A1
(43) Pub. Date: Sep. 19, 2002

(54) System and method for adjusting separate devices concurrently

(76) Inventors: Lewis B. Naron, Baton Rouge, LA (US); Humphrey M. Barlow, Vicksburg, MS (US); Clifford E. Grey JR., Vicksburg, MS (US)

Correspondence Address: HUMPHREYS ENGINEER CENTER SUPPORT ACTIVITY, ATTN: CEHEC-OC, 7701 TELEGRAPH ROAD, ALEXANDRIA, VA, 22315-3860, US

(21) Appl. No.: 10/139,373

(22) Filed: May 7, 2002

Related U.S. Application Data
(63) Continuation-in-part of application No. 09/730,556, filed on Dec. 7, 2000, now Pat. No. 6,420,816.

(51) Int. Cl. H03G 3/20

(52) U.S. Cl. 330/2; 330/129

(57) ABSTRACT

Provided is a system and method for concurrently adjusting parameters of a system incorporating separate devices. In a preferred embodiment, a series of amplifiers used in an instrumentation system are able to be adjusted and calibrated concurrently via a simple operation of an unskilled operator. One option provides for this adjustment to occur remotely from the devices.

### FIELD OF THE INVENTION

The present invention relates to control systems and more particularly to concurrent adjustment of multiple devices in a system.

### BACKGROUND

For various uses it is necessary to provide a means of converting low level voltage signals from transducers to voltage level signals by amplification of the transducer output. In such systems, a way to efficiently adjust the amplifiers is desirable.

U.S. Pat. No. 4,510,454 to Sherman, for example, discloses digitally controlled calibration of amplifiers in which the device refers to a memory for the calibration specification.

U.S. Pat. No. 5,561,395 to Melton et al., discloses an amplifier calibration system that is controlled automatically by a controller that has the specification stored in memory.

U.S. Pat. No. 5,867,060 to Burkett. Jr. et al., discloses a power delivery system for amplifiers that refers to a memory. The memory is addressed from a system controller.

### SUMMARY

A preferred embodiment of the present invention provides an apparatus and method for adjusting electrical devices concurrently. Components include: a controller; a bias circuit in operable communication with the controller and an electrical device(s) to be adjusted: a calibration circuit in operable communication with the controller and the electrical device(s); a digital-to-analog converter (DAC) in operable communication with the controller and the electrical device(s), an input device, an optional display, and an optional transmitter for operation of the apparatus remotely from the electrical device(s). The bias circuit and calibration circuit each may be DACs. The input device may be a keyboard; the optional display may be a liquid crystal display (LCD); and the optional transmitter may be a modem operating at 900 MHz.

In a preferred embodiment of the present invention, multiple amplifiers of a system, each mounted on its individual card, are adjusted via central circuits performing bias, calibration, and final gain control as centrally directed from a controller. Previously, each of these amplifiers was adjusted individually via the use of three potentiometers (pots) mounted directly on its card. One pot adjusted bias, the second pot calibrated the amplifier, and the third pot set the gain of the final stage. In a preferred embodiment of the present invention a DAC bias circuit and a DAC calibration circuit provide, respectively, the bias and calibration for all amplifier cards while a separate DAC gain control card controls the output from all of the amplifier cards. The microcontroller acts as a central processing unit (CPU), incorporating sufficient memory for providing control of multiple amplifiers, via a suitable interface that permits interchange of electromagnetic energy with the amplifiers in the system.

In a preferred embodiment of the present invention, a user, through a keypad, loads pre-specified calibration values (scaling relations) that are stored in flash memory. The calibration values are used to translate incoming signals into appropriate engineering units. A technician presses one button and each of the amplifiers in the system are set to zero, calibration is initiated and output gain automatically set to pre-specified levels within seconds. This significantly reduces setup time previously experienced in having to individually set each amplifier card, in the case of a 21 amplifier card system, for example, from an hour to a few seconds. In a preferred embodiment of the present invention, a 900 MHz modem enables a user to do the setup and calibration remotely. Previously recorded levels can be read back from memory, allowing the user to judge whether a transducer is behaving correctly. Optionally, a simple data collection routine is built into the microcontroller run time software for backing up data sent in real time to the user. Also, data may be digitized, stored in memory, and downloaded all at once via modem, for example.

### BRIEF DESCRIPTION OF THE DRAWINGS

FIG. 1 is a block diagram of a preferred embodiment of the present invention as used for adjusting a number of amplifiers.

FIG. 2 is a schematic of a circuit that may be used with the preferred embodiment of the present invention shown in FIG. 1.

FIG. 3 is a logic diagram for a preferred embodiment of the present invention.

### DETAILED DESCRIPTION

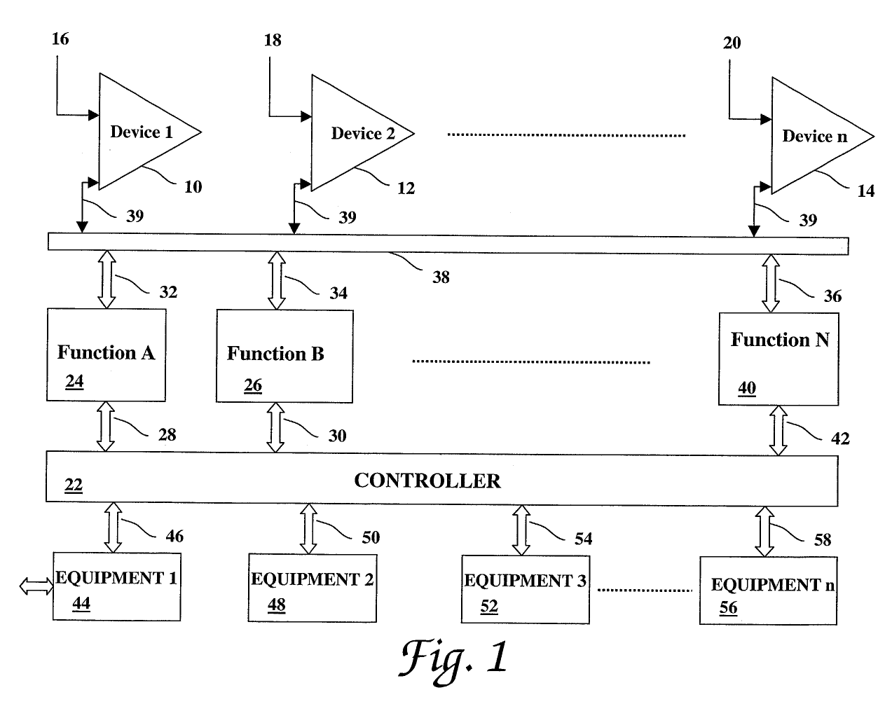

FIG. 1 is a block diagram depicting the main functions performed by a preferred embodiment. The amplifiers 16, 18, 20 to be controlled and calibrated are connected via a suitable connector 38 to the three main functions that bias 24, calibrate 26, and provide gain control 40 for them. The three main functions are controlled by a suitable microcontroller 22 that may be accessed via a keypad 52 and a modem 44, and may have a display for real time review of activities related to the control and calibration of the amplifiers 16, 18, 20. Further, a computer 56 may be provided for access to stored specifications and additional computational resources.

Referring to FIG. 1, a preferred embodiment of the present invention supports multiple amplifiers e.g., signal amplifier 10 (Amp 1), signal amplifier 12 (Amp 2) and signal amplifier 14 (Amp n). Shown is a signal input 16, e.g., an output of a transducer, to signal amplifier 10, a signal input 18 to signal amplifier 12, and a signal input 20 to signal amplifier 14. At the heart of a preferred embodiment of the present invention is a microcontroller 22 that may be embodied in a microcomputer. A preferred embodiment of the present invention also includes a bias circuit 24 and a calibration circuit 26, a DAC gain control circuit 40, an optional modem 44, an optional LCD display 48, an optional keypad 52, and a optional laptop computer 56. Further, paths 28, 30, 42, 46, 50, 54, and 58 provide operable communication from the microcontroller 22 to the bias circuit 24, the calibration circuit 26, the DAC gain control circuit 40, the optional modem 44, the optional LCD display 48, the keypad 52, and the optional laptop computer 56, respectively. The DAC gain control circuit 40 communicates with amplifiers 10, 12 and 14 via a path 36. Paths 32 and 34 provide communication between the individual amplifiers 10, 12 and 14, via a bus 38 and paths 39, for example, and the bias circuit 24 and calibration circuit 26, respectively.

### EXAMPLE

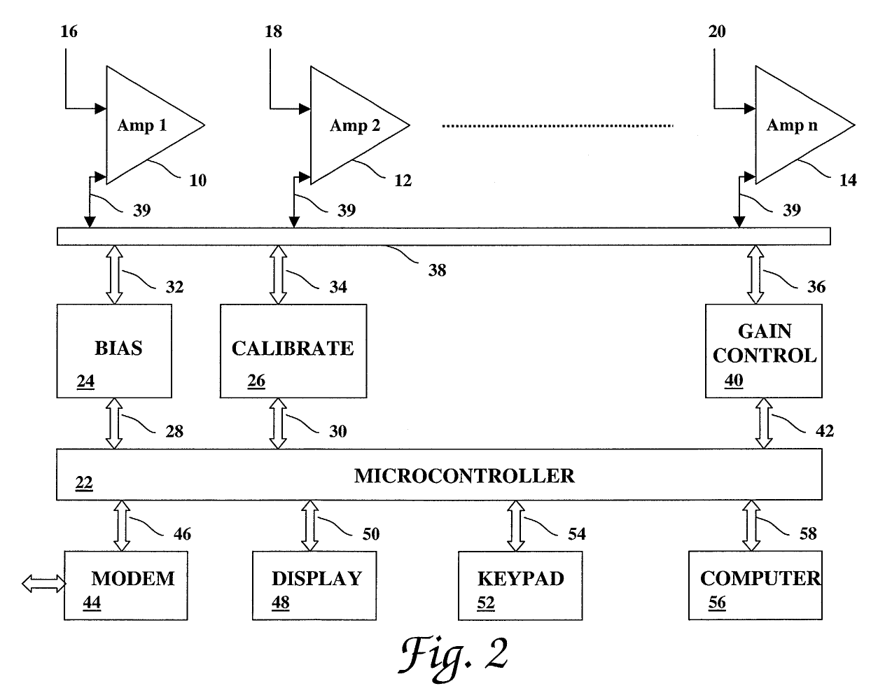

Refer to FIG. 2. A preferred embodiment of the present invention includes a circuit that may have both a positive input signal 60 and a negative input signal 62, both of which are represented by the paths 16, 18, and 20 in FIG. 1, to a differential operational amplifier 64. The differential operational amplifier 64 is in communication with a summing junction 66 that in turn is in communication with an inverting operational amplifier 68. The inverting operational amplifier 68 communicates via paths 70 and 72 with a sample and hold circuit 74, in turn in communication with a digital control switch 78 via a path 76. The digital control switch is in communication with the summing junction 66 through two paths 80 and 82. A calibration circuit 26 is in communication with a microcontroller 22 via a path 30 and also communicates with the digital control switch 78 through a path 88. A shift register 24 for balancing the amplifiers communicates with the digital control switch 78 via a path 92 and with the microcontroller 22 via a path 28. A DAC 40, used for gain control of the final stage, is fed via a path 70 and communicates with the microcontroller 22 via a path 36 and with an inverting operational amplifier 104 via a path 102.

Again refer to FIG. 2, an overview schematic of the three main stages involved in providing calibration and control of multiple amplifiers 16, 18, 20. In stage 1, an input signal is provided on paths 60, 62 to a differential amplifier 64 from a bridge sensor (not separately shown) having a low signal level. Should the input be a single-ended input, the positive path 60 is grounded and only the inverter (negative) path 62 is used. The microcontroller 22 provides a serial bit stream on path 28 to a shift register 24 that converts the serial bit stream to a parallel one on path 92 used to control a digital switch 78.

The signal from the differential amplifier 64 of Stage 1 is summed at the summing junction 66 and inverted in the inverting amplifier 68, so that the signal on path 70 is opposite in polarity to that amplified by the differential amplifier 64. The signal on path 70 is provided to a sample and hold circuit 74 on path 36 that latches this signal when commanded and produces a constant level output signal on path 76 equal to the level of the signal originally provided on path 72 at the initiation of the command.

When commanded via the microcontroller 22 using the parallel bit stream on path 88 resulting from the calibrate circuit 26, the digital switch 78 switches the latched and inverted signal on path 76 through to path 82. This signal is the exact inverse of the signal provided by the differential amplifier 66 so that when the two signals are summed in the sunning junction 66, the result is the “null signal” that biases to a null voltage level.

Upon occurrence of the null biasing, the digital switch 78 accepts the calibration signal on path 88 from the “Calibrate” circuit 26 as representative of a user-specified level initiated by the microcontroller 22. This sets up the remaining two stages. Since the other two signals have nulled each other, this calibration signal on path 80 is the only signal of consequence passed to the remaining stages over the summing junction 66. It is passed through the inverting amplifier 68 over path 70 to the DAC 40 that serves to control the gain of the amplifiers 16, 18, 20.

The DAC 40 varies an output voltage on path 102 that tracks the input voltage on path 60, 62 in a linear relationship. That is, the output voltage is equal to the input voltage multiplied by a constant, the value of the constant can be greater than 1 or a fraction, being provided over path 36 from a user-specified value in the microcontroller 22 to the DAC 40. Thus, the DAC, not normally used for gain control, provides gain control in Stage 2.

Upon setting the gain in Stage 2, the calibration signal from the DAC 40 is passed over path 102 to a second inverter amplifier 104 to reverse the polarity of the signal to that of the initial input signal on path 60, 62. The output of the second inverter amplifier 104 is provided on path 108 to calibrate, bias, and provided gain control to amplifiers 16, 18, 20.

When measurements are being recording using the amplifiers 16, 18, 20, the calibration signal from path 108 is removed via a command provided via the digital switch 78, since the calibration is used only at times of initial setup and periodic calibration. Being able to readily calibrate multiple devices, such as amplifiers 16, 18, 20, enables each device to convert signals from sensors, such as transducers, to signal levels that are all in an appropriate range for easy digitizing.

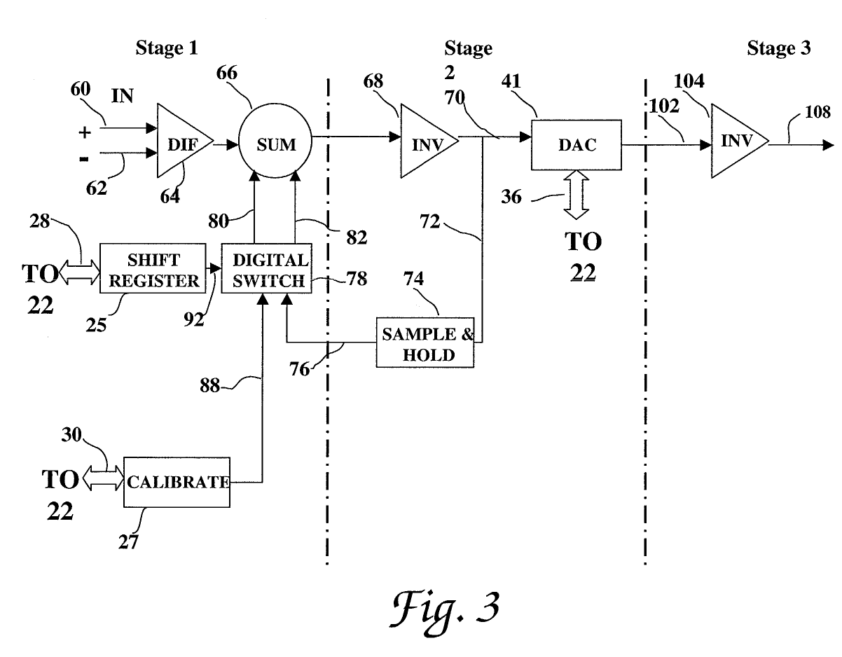

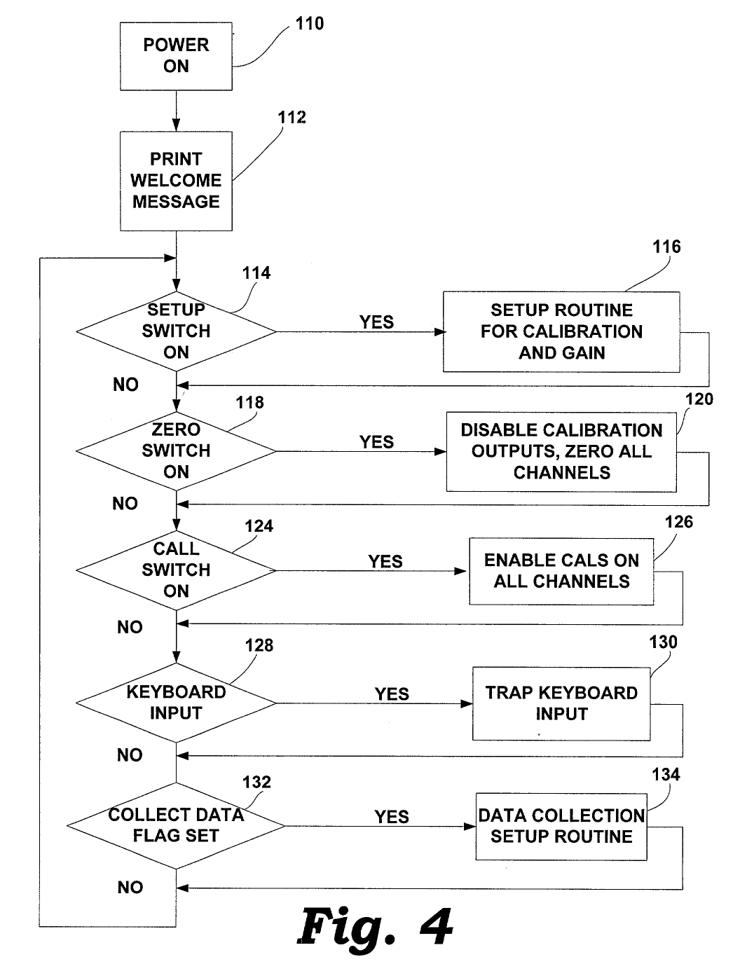

Refer to FIG. 3 for the logic chart of a preferred embodiment of the present invention. A preferred embodiment of the present invention is powered on 110 and a welcome message is printed 112. If a setup switch 114 is set to on, a setup routine for calibration and gain setup 116 is initiated. If the setup switch 114 is not set to on the next operation determines if the zero switch 118 has been set to on. If the setup switch 114 was set on, the setup routine 116 was initiated, and the zero switch 118 was set to on, the calibration outputs are disabled and all amplifier channels are set to zero 120. If neither the setup switch 114 nor the zero switch 118 are set to on, the next operation is at the calibration switch 124. After disabling calibration and zeroing all channels, the calibration switch 124 may be set to on or left off. If it is set to on, calibration is enabled on each channel associated with an amplifier card. If not set to on, the next step is keyboard input 128. If neither the setup 114, zero 118, nor calibration 124 switches are set to on, the next step is keyboard input 128. If calibration has been enabled 126 and there is a keyboard input 128, the keyboard input 128 is captured or “trapped” 130 for further use. If neither the setups 114, zero 118, nor the calibration 124 switches are set to on and no keyboard input 128 is made, the next step is data collection 132. If the keyboard input 128 has been trapped 130, then a collect data flag 132 is set and a data collection setup routine 134 is initiated. If none of switches 114, 118, 124 are set to on and there is no keyboard input 128, the collect data flag is set 132 and the operation may be reiterated at the input to the setup switch 114. If the data collection setup routine 134 has been initiated for a particular data set, the system is now available for re-set and reiteration at the setup switch 114.

It will be appreciated that the above-described apparatus discloses means for quickly and efficiently calibrating multiple amplifiers arranged in a system such as may be used in an instrumentation setup for taking test data.

While the present invention has been described in connection with the preferred embodiments of the various elements, it is to be understood that other similar embodiments may be used or modifications and additions may be made to the present described embodiment for performing the same function of the present invention without deviating therefrom. Therefore, the present invention should not be limited to any single embodiment, but rather construed in breadth and scope in accordance with the recitation of the appended claims.

We claim:

21. A system for concurrently adjusting at least one device comprising:
at least one controller in operable communication with said at least one device;
at least one bias circuit in operable communication with said controller and said at least one device;
at least one calibration circuit in operable communication with said at least one controller and said at least one device; and
at least one gain control circuit in operable communication with said controller and said at least one device,
wherein, as an option, said system is operated at a location remote from said at least one device.

22. The system of claim 21 in which said at least one device comprises at least one electrical device.

23. The system of claim 21 in which said at least one device comprises at least one amplifier.

24. The system of claim 21 in which said controller is a microcontroller.

25. The system of claim 24 in which said microcontroller is incorporated in a computer.

26. The system of claim 21 further comprising at least one modem in operable communication with said controller,
wherein said at least one modem enables remote adjustment of said at least one device.

27. The system of claim 21 further comprising at least one display in operable communication with said controller.

28. The system of claim 27 in which said display is selected from the group consisting of: a cathode ray tube (CRT), a liquid crystal display (LCD), a screen employing flat panel technology, a digital gauge, an analog gauge, and any combination thereof.

29. The system of claim 21 further comprising at least one interface to a laptop computer.

30. The system of claim 21 in which said calibration circuit comprises, at least in part, a digital to analog converter.

31. The system of claim 21 in which said bias circuit comprises, at least in part, a digital to analog converter.

32. The system of claim 21 in which said gain control circuit comprises, at least in part, a digital to analog converter.

33. A method for adjusting at least one parameter of at least one device concurrently, comprising:
providing at least one controller, incorporating memory that is, at least in part, programmed with software, in operable communication with said at least one device;
providing at least one bias circuit in operable communication with said controller and said at least one device;
providing at least one calibration circuit in operable communication with said at least one controller and said at least one device; and
providing at least one gain control circuit in operable communication with said controller and said at least one device, and
integrating operation of said at least one bias circuit, said at least one calibration circuit, and said at least one gain control circuit under the control of said at least one controller,
wherein said at least one device is able to be concurrently biased, calibrated, and have its final stage gain controlled via a simple operation by an unskilled user, and
wherein, as an option, said system is operated remotely from said at least one device.

34. The method of claim 33 further comprising reading back from memory previously recorded output levels of said devices,
wherein, a user is able to judge whether an apparatus providing input to said at least one device is operating within pre-specified limits.

35. The method of claim 33, further comprising building a data collection routine into said software for backing up data sent in real time to a user.

36. The method of claim 33 further comprising digitizing data for storage in said memory,
wherein, said data is downloaded all at once.

37. A method for using a system, incorporating a) at least one signal distribution channel, b) at least one setup switch, c) at least one zero switch, d) at least one calibration switch, e) at least one keyboard, f) at least some memory capable of storing both data and software, and g) operable communications among the above, to adjust concurrently at least one parameter of at least one device, comprising the steps of:
powering up said system;
setting said at least one setup switch to on,
wherein, a software routine for calibration and gain control is initiated;
setting said at least one zero switch to on,
wherein, at least one calibration output is disabled and all channels are set to zero;
setting said at least one calibration switch to on,
wherein, calibration is enabled on each said at least one channel associated with said device;
inputting information via said at least one keyboard,
wherein, said information is trapped within said memory for further use; and
setting at least one collect data flag,
wherein, at least one data collection setup routine is initiated, having enabled concurrent adjustment of the bias and final stage gain and the calibration of said device via the completion of all steps in said method, and
wherein, said device may be operated in an optimum mode for its intended purpose.

38. The method of claim 37 further comprising providing a welcome message after said powering up of said system.

39. The method of claim 37 in which a reiteration of said steps is enabled without powering said system off.
